(19) United States
(12) Patent Application Publication
(10) Pub. No.: US 2025/0343055 A1
(43) Pub. Date: Nov. 6, 2025

(54) ONE-STOP CLEANING METHOD AND SYSTEM FOR SEMICONDUCTOR CARRIER

(71) Applicant: GUDENG PRECISION INDUSTRIAL CO., LTD., New Taipei City (TW)

(72) Inventors: MING-CHIEN CHIU, New Taipei City (TW); CHIA-HO CHUANG, New Taipei City (TW); KUO-HUA LEE, New Taipei City (TW); XIN-YUAN HUANG, New Taipei City (TW)

(73) Assignee: GUDENG PRECISION INDUSTRIAL CO., LTD., New Taipei City (TW)

(21) Appl. No.: 19/194,041

(22) Filed: Apr. 30, 2025

Related U.S. Application Data
(60) Provisional application No. 63/641,429, filed on May 2, 2024.

(51) Int. Cl. H01L 21/67; B08B 3/12

(52) U.S. Cl. CPC H01L 21/67034; B08B 3/12; H01L 21/6704

(57) ABSTRACT

A one-stop cleaning system and method for a semiconductor carrier. The method includes steps of disassembly, classification, nanobubble washing and negative pressure vacuum drying. The system includes multiple cleaning chambers, a nanobubble generator, a drainage device, and a negative pressure vacuum drying device. With one-stop integration of the steps of disassembly, classification, nanobubble washing and negative pressure vacuum drying, contaminants and organic compounds of a semiconductor carrier can be effectively removed to provide application suitability for cleaning a semiconductor carrier.

### CROSS-REFERENCE TO RELATED APPLICATION

This non-provisional application claims priority under 35 U.S.C. § 119(e) on U.S. provisional Patent Application No. 63/641,429 filed on May 2, 2024, the entire contents of which are hereby incorporated by reference.

### BACKGROUND OF THE INVENTION

### 1. Field of the Invention

The present disclosure relates to a cleaning method and system for a semiconductor carrier, and in particular to a one-stop cleaning method and system for a semiconductor carrier.

### 2. Description of the Related Art

For semiconductor carriers commonly used for protecting, storing and transporting semiconductor workpieces in the semiconductor industry, interiors of these semiconductor containers may become contaminated due to various factors such as manufacturing processes and environments and thus need cleaning. The semiconductor workpieces can be pieces of wafer, reticles, printed circuit boards (PCBs), carriers or other electronic components, and the semiconductor containers can be wafer carrier pods, reticle carrier pods, PCB carrier pods or other electronic component carrier pods, for example, Front Opening Unified Pods (FOUP).

Among these semiconductor carriers, individual components of the semiconductor carriers may become contaminated due to various factors such as manufacturing processes and environments. Due to extremely high levels of cleanliness necessarily maintained in semiconductor processing equipment and semiconductor carriers, semiconductor carriers need to be cleaned to ensure their cleanliness and improve the yield rate of semiconductor processes.

However, conventional techniques for cleaning semiconductor carriers in the prior art mostly use numerous workstations to perform cleaning, drainage and drying. Each of the existing workstations performs one single function, in a way that processes for performing different functions on a semiconductor carrier and its components necessarily involve moving among the individual stations, resulting in complicated processes, time needed for moving and space occupied by equipment. In addition, for most semiconductor carriers and their components, deionized water (DIW) is used for rinsing followed by drying. However, the approach above provides a rather limited cleaning effect, and may fall short in further improving issues of harmful gas residuals of volatile organic compounds (VOC), toluene and isopropanol.

Therefore, there is a need for a quick cleaning method and system for a semiconductor carrier, with the method and system integrated with multiple functions so as to be able to effectively remove volatile organic compounds, toluene and isopropanol and improve cleaning effects for a semiconductor carrier.

### BRIEF SUMMARY OF THE INVENTION

In view of the above, a cleaning method for a semiconductor carrier and a cleaning system for a semiconductor carrier provided by the present disclosure are able to achieve a comprehensive one-stop cleaning process within one cleaning system. In addition to performing differentiated cleaning on components of each semiconductor carrier, residual contaminants and volatile organic compounds can also be effectively removed, while the space required for configuring cleaning equipment and a lengthy operation time of cleaning procedures in different stops can be reduced.

A one-stop cleaning method for a semiconductor carrier provided according to an embodiment of the present disclosure includes steps of: a disassembly step of disassembling a semiconductor carrier to be cleaned into multiple components; a classification step of classifying the multiple components and placing the multiple components into cleaning chambers of corresponding classes; a nanobubble washing step of cleaning the components in the individual cleaning chambers by the individual cleaning chambers according to cleaning processes set according to characteristics of the components to be cleaned; and a negative pressure vacuum drying step of drying the components inside the individual cleaning chambers by the individual cleaning chambers.

In one embodiment, in the nanobubble washing step, a cleaning fluid is transported to the cleaning chamber by the nanobubble generator to fully clean micropores of the component.

In one embodiment, the cleaning fluid is deionized water mixed with carbon dioxide, ozone or ammonia.

In one embodiment, in the nanobubble washing step, the cleaning chamber is provided with an ultrasonic vibration device, and the cleaning fluid in the cleaning chamber is stirred by generating high-frequency sound wave vibration to clean the component by means of performing ultrasonic vibration.

In one embodiment, in the nanobubble washing step, the cleaning chamber is provided with a heating device for heating the cleaning fluid in the cleaning chamber.

In one embodiment, after the cleaning fluid is heated, a soaking step is further included to soak the component until a predetermined decontamination condition is met, wherein the predetermined decontamination condition is that 50% or more of decontamination of the component is met.

In one embodiment, in the nanobubble washing step, the cleaning process includes controlling and setting parameters by a backend system to accordingly correspond to cleaning conditions of all of the components of different classes.

In one embodiment, the nanobubble washing step further includes an overflow step for circulating and replacing the cleaning fluid in the cleaning chamber.

In one embodiment, before the negative pressure vacuum drying step, a drainage step is further included to fully discharge the cleaning fluid from the cleaning chamber and eliminating partial fluid attached to the component.

A one-stop cleaning system for a semiconductor carrier provided according to another embodiment of the present disclosure is adapted to clean the semiconductor carrier which includes multiple components of different classes. The cleaning system for a semiconductor carrier includes: multiple cleaning chambers, each of the cleaning chambers arranged with the multiple components of different classes; and at least one nanobubble generator, coupled to the cleaning chambers, the nanobubble generator for transporting a cleaning fluid to at least one of the cleaning chambers to fully clean micropores of the component; wherein the cleaning chamber includes: at least one drainage device, arranged at the cleaning chamber, the drainage device fully discharging the cleaning fluid from the cleaning chamber and eliminating partial fluid attached to the component; and at least one negative pressure vacuum drying device, arranged at the cleaning chamber, the negative pressure vacuum drying device for drying the component in the cleaning chamber; wherein the cleaning chamber, the nanobubble generator, the drainage device and the negative pressure vacuum drying device operate in sequence, and processes from cleaning to drying for the component are completed in a one-stop manner.

In one embodiment, the cleaning system for a semiconductor carrier further includes a disassembly device to disassemble and separate the components of the different classes of the semiconductor carrier, and transports the same to the corresponding cleaning chambers.

In one embodiment, the cleaning system for a semiconductor carrier further includes an ultrasonic vibration device arranged in the cleaning chamber, the ultrasonic vibration device stirring the cleaning fluid in the cleaning chamber by generating high-frequency sound wave vibration to clean the component by means of performing ultrasonic vibration.

In one embodiment, the cleaning system for a semiconductor carrier further includes at least a heating device arranged in the cleaning chamber, the heating device for heating the cleaning fluid in the cleaning chamber.

In one embodiment, the cleaning system for a semiconductor carrier further includes a backend system for controlling the cleaning chamber, the nanobubble generator, the drainage device and the negative pressure vacuum drying device to operate in sequence, such that processes from cleaning to drying for the component are completed in a one-stop manner.

In one embodiment, each of the cleaning chambers further includes an overflow port, and a circulation space in the cleaning chamber is defined between the overflow port and the nanobubble generator to circulate and replace the cleaning fluid in the cleaning chamber.

In one embodiment, the cleaning fluid is deionized water mixed with carbon dioxide, ozone or ammonia.

With the cleaning method for a semiconductor carrier and the cleaning system for a semiconductor carrier of the present disclosure, cleaning effects for a semiconductor carrier can be enhanced to further improve the issues of harmful substances such as volatile organic compounds (VOC), toluene and isopropanol remaining in a semiconductor carrier, and a comprehensive one-stop cleaning process within one cleaning system can be effectively achieved. In addition, differentiated cleaning can be performed with respect to each semiconductor carrier and its components, further achieving the effect of reducing the space needed for configuring cleaning equipment and a lengthy operation time of cleaning procedures in different stops.

### BRIEF DESCRIPTION OF THE DRAWINGS

FIG. 1 is a flowchart of a cleaning method for a semiconductor carrier according to an embodiment of the present disclosure.

FIG. 2A to FIG. 2E are sub-flowcharts of a nanobubble washing step of a cleaning method for a semiconductor carrier according to an embodiment of the present disclosure.

FIG. 3 is a flowchart of a cleaning method for a semiconductor carrier according to an embodiment of the present disclosure.

FIG. 4 is a block diagram of a cleaning system for a semiconductor carrier according to an embodiment of the present disclosure.

FIG. 5 is a block diagram of a cleaning system for a semiconductor carrier according to an embodiment of the present disclosure.

FIG. 6 is a block diagram of a cleaning system for a semiconductor carrier according to an embodiment of the present disclosure.

FIG. 7 is a block diagram of a cleaning system for a semiconductor carrier according to an embodiment of the present disclosure.

FIG. 8 is a block diagram of a cleaning system for a semiconductor carrier according to an embodiment of the present disclosure.

FIG. 9 is a block diagram of a cleaning system for a semiconductor carrier according to an embodiment of the present disclosure.

FIG. 10 is a partial configuration diagram of a cleaning system for a semiconductor carrier according to an embodiment of the present disclosure.

FIG. 11 is a partial configuration diagram of a cleaning system for a semiconductor carrier according to an embodiment of the present disclosure.

### DETAILED DESCRIPTION OF THE INVENTION

The technical contents of the present disclosure are to be further described in detail by way of embodiments with the accompanying drawings below. A person skilled in the art would be able to understand the objects, features and effects of the present disclosure on the basis of the disclosure of the present application. It should be noted that, the present disclosure may be implemented or applied by other specific embodiments, and changes and modifications may also be made on the basis of different perspectives and applications to various details in the description without departing from the spirit of the present disclosure. Technical contents associated with the present disclosure are described in detail below, and it should be noted that the disclosure is not to be construed as limitations to the scope of claims of the present disclosure.

It should be noted that, in the present disclosure of the literature, terms such as “first”, “second” and “third” are used to distinguish differences among elements, and are not to be construed as limiting to the elements themselves or specific orders of the elements. Moreover, in the present disclosure of the literature, a specific number is specified, the article “a/an/one” refers to one element or more. In addition, the various steps described in the present application can be performed sequentially, in a reverse order, or by appropriately changing or skipping a step in the order during a control process. Moreover, It should be noted that, the expression “a first step can be performed subsequent to a second step” described in the present application can be interpreted as “a first step directly follows after a second step is completely performed”, or can interpreted as “another step (for example, a third step) follows after a second step is completely performed and a first step follows subsequently”.

Moreover, the term “coupled” in the present application can be interpreted as “directly connected” and/or “indirectly connected”. More specifically, “a first element configured to be coupled with a second element” can be interpreted as “a first element configured to be directly connected with a second element” and/or “a first element configured to be indirectly connected with a second element”.

A one-stop cleaning device for a semiconductor carrier disclosed according to an embodiment of the present disclosure is adapted to clean carrier, container and related components of a semiconductor process, such as cleaning a wafer carrier pod, a reticle carrier pod, a carrier board carrier pod or a carrier (which can also be referred to as “a container” in the present literature) of other elements of a semiconductor process, and such as a housing, a box, a support member, a limiter, a door panel or a tray of a carrier; however, the present disclosure is not limited to the examples above.

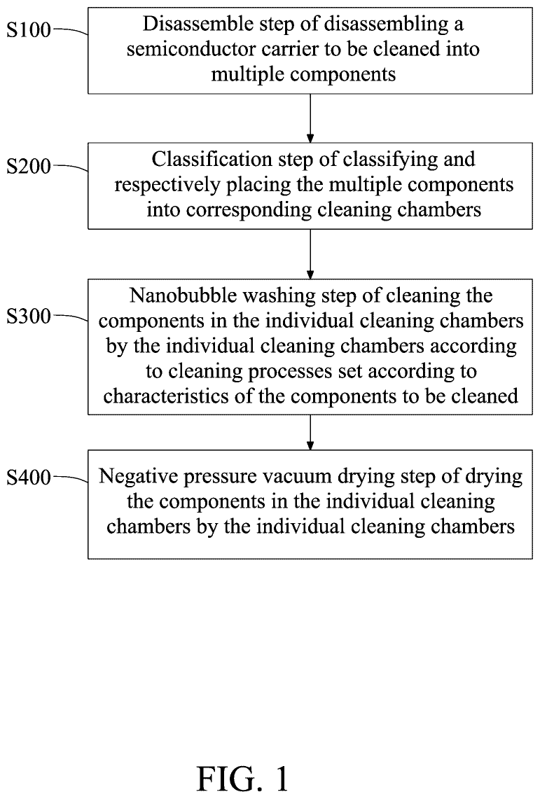

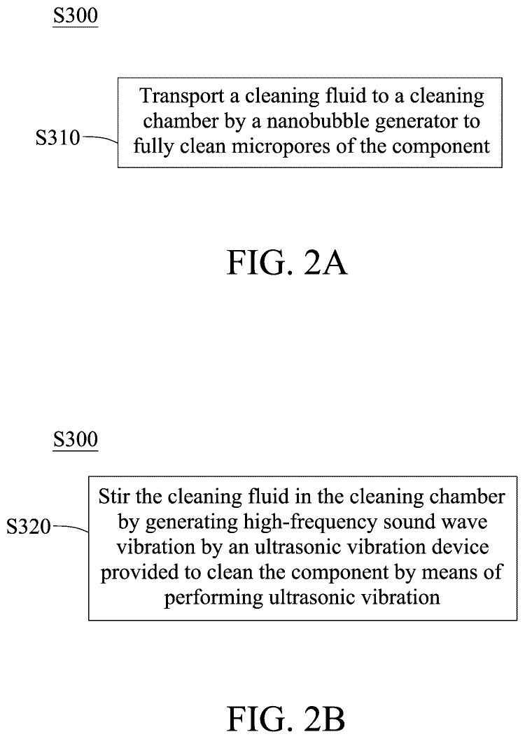

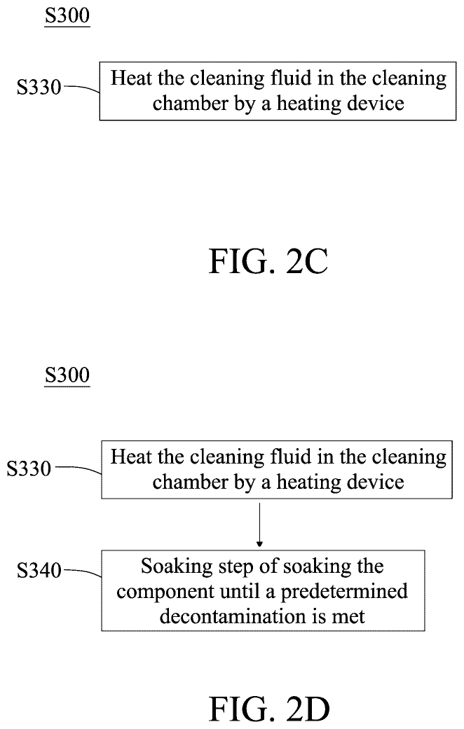

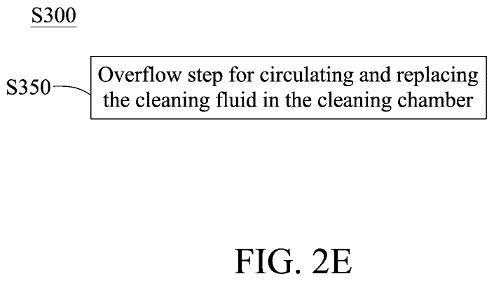

FIG. 1 shows a flowchart of a cleaning method for a semiconductor carrier according to an embodiment of the present disclosure. FIG. 2A to FIG. 2E show sub-flowcharts of a nanobubble washing step of a cleaning method for a semiconductor carrier according to an embodiment of the present disclosure.

Referring to FIG. 1, the cleaning method for a semiconductor carrier provided by the present disclosure is adapted to be performed by, for example, an electronic device, and the cleaning method can be specifically completed by step S100 to step S400 shown in FIG. 1 to carry out a one-stop cleaning process, so as to perform differentiated cleaning on each semiconductor carrier and its components and effectively remove residual contaminants and volatile organic compounds. It should be noted that the numerals of the steps are merely illustrative and are not to be construed as limitations to an operation order. The electronic device may be a desktop computer, a laptop computer, a tablet computer, a workstation, a server, a cloud server or a smartphone, and may be a device such as a microcomputer, a processor, a circuit board, and a central processing unit (CPU). Moreover, the electronic device may directly or indirectly provide a user interface for a user to operate. Alternatively, the electronic device may indirectly perform the method above by other electronic devices by means of transmitting electrical signals with other electronic devices, or the electronic devices may operate collaboratively. Moreover, the electronic device may include an output module to provide a visual display or an audio output such as a display, a touch screen, a control panel, projection, three-dimensional projection, a speaker or phone audio; and an input module such as a keyboard, a mouse, a handle, a touch screen, dynamic detection or voice recognition. It should be noted that the method is not limited to being performed by the electronic device above.

The process of the cleaning method for a semiconductor carrier according to an embodiment of the present disclosure is described below.

Referring to FIG. 1, step S100 is a disassembly step of disassembling a semiconductor carrier to be cleaned into multiple components. In one embodiment, the semiconductor carrier is, for example, a Front Opening Unified Pods (FOUP), and the multiple disassembled components are, for example, a pod body and a cover of the FOUP, wherein the pod body is for placing wafer and the cover is for covering the pod body; however, the disassembled components are not limited to the examples above. In some embodiments, the semiconductor carrier may be further disassembled into different components. With the disassembly step, the semiconductor carrier may be disassembled into different components. These different components have different characteristics, for example, sizes, shapes, physical properties and chemical properties, and can correspond to different subsequent processing processes.

Referring to FIG. 1, step S200 is a classification step of classifying the multiple components and respectively placing the multiple components into cleaning chambers of corresponding classes. In one embodiment, the cleaning method for a semiconductor carrier provides at least one cleaning chamber for placing a component of a corresponding class. The class may be predetermined, for example, the pod body of the semiconductor carrier is a first class, and the cover of the semiconductor carrier is a second class; however, the present disclosure is not limited to the examples above. Thus, with the classification step, the disassembled components obtained from the disassembly step are classified and placed into the cleaning chambers of the corresponding classes according to a result of the classification, so as to place the components of different classes into different cleaning chambers to facilitate subsequent cleaning processes for the different components.

Referring to FIG. 1, step S300 is a nanobubble washing step of cleaning the components in the individual cleaning chambers by the cleaning chambers with the cleaning processes set according to the characteristics of the components to be cleaned. In one embodiment, the different components to be cleaned have different corresponding cleaning processes, for example, different cleaning times and cleaning strengths; that is, the different cleaning chambers have different cleaning processes, or may have the same cleaning processes according to the classes and properties of the components. Moreover, the cleaning processes may be set in advance according to the characteristics of the different components. In one embodiment, the nanobubble washing step generates fine bubbles by such as a nanobubble generator, for example, generating ultra-fine bubbles (UFB), so as to remove contaminants and chemical substances from the components to be cleaned by the tiny bubbles.

Referring to FIG. 1 and FIG. 2A, in one embodiment, the nanobubble washing step of step S300 further includes sub-step S310 of transporting a cleaning fluid to the one or more cleaning chambers above by the nanobubble generator to fully clean micropores of the components, wherein the cleaning fluid is a cleaning fluid having nanobubbles. In one embodiment, the cleaning fluid is deionized water mixed with carbon dioxide, ozone and/or ammonia. It should be noted that, for different components, different characteristics of the components and different cleaning processes, the nanobubble washing step may provide cleaning fluids of different properties, for example, cleaning fluids having different numbers of nanobubbles, different flows, different pressures and different bubble sizes, so as to provide different components with different cleaning effects; however, the present disclosure is not limited to the examples above.

Referring to FIG. 1, step S400 is a negative pressure vacuum drying step of drying the internal components by the individual cleaning chambers. In one embodiment, each of the cleaning chambers is arranged with a drying device, for example, a negative pressure vacuum drying device, and the drying step may be performed by means of temperature or blowing, or may be performed with the assistance of negative pressure and/or vacuum, so as to dry the components in the cleaning chamber. In one embodiment, the negative pressure vacuum drying step may be performed after the nanobubble washing step so as to dry the cleaned components. In one embodiment, the negative pressure vacuum drying step may be performed before the nanobubble washing step to bake the components in advance, such that, for example, volatile organic compounds attached to surfaces or the components may first be released to the surfaces, and such related volatile organic compounds can be more effectively removed when the nanobubble washing step is later performed. In one embodiment, the negative pressure vacuum drying step may be performed both before and after the nanobubble washing step so as to bake the components in advance and dry the cleaned components after washing.

In one embodiment, step S100 to step S400 above may be completed by one single machine or one single stop, so as to achieve integrated one-stop cleaning for a semiconductor carrier, further improve cleaning efficiency and reducing the space needed for configuring cleaning stations and a lengthy operation time of cleaning procedures in different stops. Meanwhile, with step S100 to step S400 above, differentiated cleaning can be provided for characteristics of different components to effectively remove the contaminants and/or volatile organic substances from the individual components.

Referring to FIG. 1 and FIG. 2B, in one embodiment, the nanobubble washing step of step S300 further includes sub-step S320 of stirring the cleaning fluid in the cleaning chamber by generating high-frequency sound wave vibration by an ultrasonic vibration device provided in the cleaning chamber to clean the components by means of performing ultrasonic vibration. In one embodiment, by providing the ultrasonic vibration device in the cleaning chamber, and stirring the cleaning fluid in the cleaning chamber by generating high-frequency sound wave vibration using the ultrasonic vibration device, cleaning of the components is reinforced by means of ultrasonic vibration to improve the efficiency of removing the contaminants and chemical substances from the components. In one embodiment, the amplitude and frequency of ultrasonic waves generated by the ultrasonic vibration device are adjustable, and are also adjustable according to the properties of different components.

Referring to FIG. 1 and FIG. 2C, in one embodiment, the nanobubble washing step of step S300 further includes sub-step S330 of heating the cleaning fluid in the cleaning chamber by a heating device provided in the cleaning chamber. In one embodiment, by providing a heating device in the cleaning chamber, wherein the heating device may be, for example, an electric heater, a heating panel or a hot steam generating device, the cleaning fluid in the cleaning chamber is heated to improve the efficiency of separating the contaminants and chemical substances from the components. In one embodiment, the heating temperature is adjustable, and is also adjustable according to the properties of different components.

Referring to FIG. 1 and FIG. 2D, in one embodiment, the nanobubble washing step of step S300 further includes sub-step S340 of a soaking step of soaking the components until a predetermined decontamination condition is met. The decontamination condition may be that 50% or more of decontamination of the component is met; however, the present disclosure is not limited to the examples above. For different types of components and corresponding to different cleaning chambers, different predetermined decontamination condition can be set. In one embodiment, after heating in step S330, the soaking step of step S340 is sequentially performed to keep soaking the component in the cleaning chamber in the cleaning liquid until the predetermined decontamination condition is met. In one embodiment, the decontamination conditions is that 50% or more of decontamination is met. In one embodiment, the soaking step of step S340 may be performed independently, and is not limited to being performed successive to the heating step S330. Thus, with the soaking step, an active time of the cleaning fluid upon the contaminants and chemical substances on the component can be increased to improve cleaning effects. In one embodiment, the soaking step may be performed with the assistance of the ultrasonic vibration and/or an input of nanobubbles above so as to improve decontamination effects during the soaking.

Referring to FIG. 1 and FIG. 2E, in one embodiment, the nanobubble washing step of step S300 further includes sub-step S350 of an overflow step for circulating and replacing the cleaning fluid in the cleaning chamber. In one embodiment, the cleaning chamber is provided with an overflow port for discharging the cleaning fluid from the cleaning chamber and at the same time continually inputting the cleaning fluid to circulate and replace the cleaning fluid in the cleaning chamber, thereby discharging the cleaning fluid carrying the contaminants and/or chemical substances and replacing the same with a clean cleaning fluid and hence preventing secondary contamination of the components and improving cleaning effects.

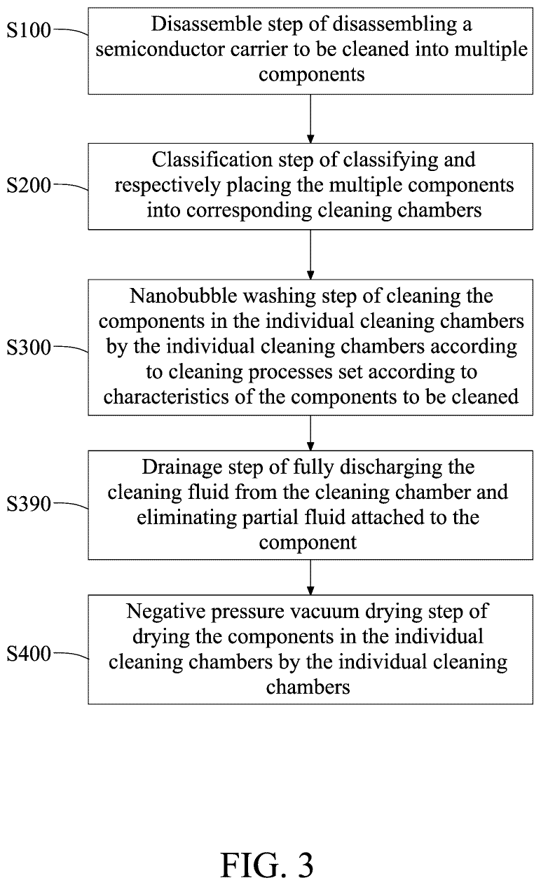

FIG. 3 shows a flowchart of a cleaning method for a semiconductor carrier according to an embodiment of the present disclosure.

Referring to FIG. 3, in one embodiment, the cleaning method for a semiconductor carrier according to an embodiment of the present disclosure further includes step S390 of a drainage step, which is performed before the negative pressure vacuum drying step of step S400. In the drainage step of step S390, the cleaning fluid is fully discharged from the cleaning chamber and partial fluid attached to the component is eliminated. In one embodiment, after the component has undergone the nanobubble washing step of step S300, the cleaning fluid can be fully discharged from the cleaning chamber by the drainage step of step S390, and spinning is performed to drain the component by means such as generating a centrifugal force by rotations of centrifugal force generating mechanism. More specifically, for example, the component may be clamped by fixture to undergo spinning and drainage. Thus, the cleaning fluid can be eliminated in advance from the cleaning chamber and the component before the negative pressure vacuum drying step of step S400 for better subsequent drying efficiency.

In one embodiment, in the nanobubble washing step of step S300, the cleaning process controls and sets parameters by a backend system to accordingly correspond to cleaning conditions of all of the components of different classes. In one embodiment, the backend system may be, for example, the electronic device above in any form, so as to provide a device and/or a user interface for controlling and setting parameters, and may be signally coupled to the devices or equipment corresponding to the individual steps above, or may correspond to different classes of components and be stored with at least one cleaning process so as to perform the individual steps of the cleaning method for a semiconductor carrier above and control the individual steps to be performed sequentially.

On the basis of the above, the cleaning chamber provided by the cleaning method for a semiconductor carrier according to an embodiment of the present disclosure may include integrated one-stop functions such as cleaning, heating, drainage, drying and negative pressure vacuum baking, wherein the individual functions can provide different cleaning processes set with different parameters according to characteristics of different components to improve cleaning effects. For example, when the steps of the functions of steam heating, drying or negative pressure vacuum baking are performed, the corresponding cleaning chambers may be provided with different parameter settings to perform different cleaning processes according to different levels of heat resistance of the individual components, so as to improve the cleaning performance for the individual components. Moreover, the sequence for performing the individual functions provided by the cleaning method for a semiconductor carrier is not specifically defined. For example, for a predetermined component, an execution sequence for the cleaning chamber may be cleaning, drainage and baking. For another component, an execution sequence for the cleaning chamber may be baking, cleaning, drainage and drying. Thus, after the component is first baked, internal substances such as volatile organic compounds can be first released to float on the surface of the component, and then the surface floats can then be removed when cleaning is later performed by the cleaning fluid, hence improving cleaning effects. Furthermore, the steps provided by the cleaning method for a semiconductor carrier according to an embodiment of the present disclosure allow the individual cleaning steps to be completed at a same station, and the individual functional steps are integrated to improve cleaning efficiency for the semiconductor carrier.

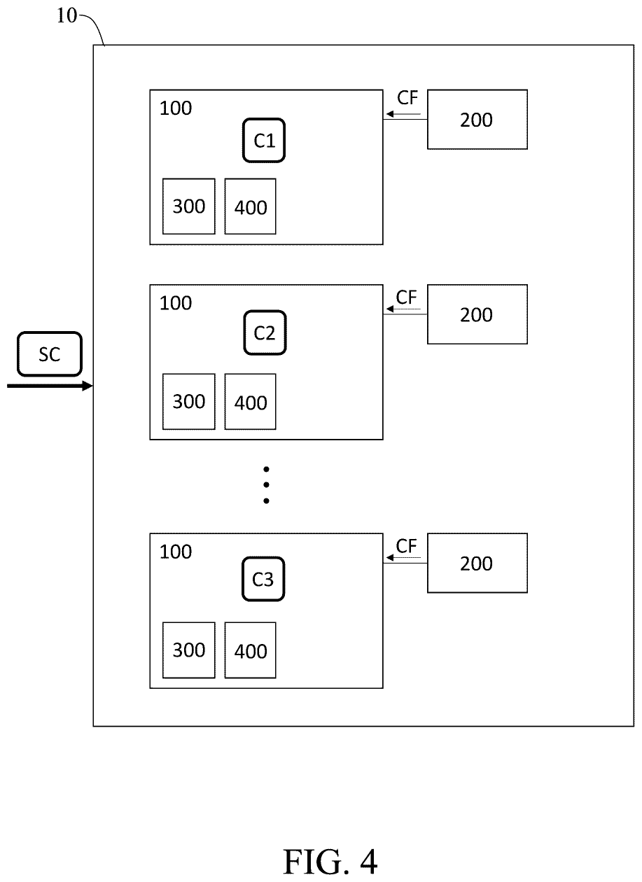

FIG. 4 to FIG. 9 show block diagrams of a cleaning system for a semiconductor carrier according to several embodiments of the present disclosure.

Referring to FIG. 4, a semiconductor carrier cleaning system 10 provided according to another embodiment of the present disclosure is adapted to clean a semiconductor carrier SC. The semiconductor carrier SC includes multiple components of different classes, for example, a first component C1, a second component C2 and a third component C3, wherein each component is a pod body or a cover of the semiconductor carrier SC; however, the present disclosure is not limited to the examples above.

Referring to FIG. 4, the semiconductor carrier cleaning system 10 includes multiple cleaning chambers 100, at least one nanobubble generator 200, at least one drainage device 300 and at least one negative pressure vacuum drying device 400.

In one embodiment, each of the multiple cleaning chambers 100 is arranged with components of different classes; for example, as shown in FIG. 4, part of the cleaning chambers 100 is arranged with the first component C1, part of the cleaning chambers 100 is arranged with the second component C2, and part of the cleaning chambers 100 is arranged with the third component C3. The different components have different corresponding properties, for example, different sizes, different structural strengths and different levels of heat resistance.

In one embodiment, the nanobubble generator 200 is coupled to the cleaning chambers 100, and is for transporting a cleaning fluid CF to at least one of the cleaning chambers 100 to fully clean micropores of the component (for example, the first component C1 and/or the second component C2). In one embodiment, each of the cleaning chambers 100 is arranged with one corresponding nanobubble generator 200. In one embodiment, one nanobubble generator 200 may be configured to provide the cleaning fluid CF to several cleaning chambers 100. In one embodiment, the nanobubble generator 200 is for generating fine air bubbles, for example, generating ultra-fine bubbles (UFB) and dissolving the nanobubbles in the cleaning fluid CF, so as to remove contaminants and chemical substances from the components to be cleaned by these tiny bubbles. In one embodiment, the cleaning fluid CF is deionized water mixed with carbon dioxide, ozone and/or ammonia. In one embodiment, for different components in cleaning chambers 100 and different characteristics of the components, the nanobubble generator 200 may provide different cleaning processes, for instance, the cleaning fluid CF in different properties, for example, the cleaning fluid CF having different numbers of nanobubbles, different flows, different pressures and different bubble sizes, so as to provide different components with different cleaning effects; however, the present disclosure is not limited to the examples above.

In one embodiment, the cleaning chamber 100 includes at least one drainage device 300 and at least one negative pressure vacuum drying device 400. The drainage device 300 is arranged at the cleaning chamber 100, and fully discharges the cleaning fluid CF from the cleaning chamber 100 and eliminates partial fluid attached to the component. The negative pressure vacuum drying device 400 is arranged at the cleaning chamber 100, and is for drying the component (for example, the first component C1 and/or the second component C2) in the cleaning chamber 100. The so-called “arranged at” the cleaning chamber 100 may refer to being arranged in the cleaning chamber 100 or be integrated at the cleaning chamber 100 such as next to the cleaning chamber 100. In one embodiment, the drainage device 300 performs spinning to drain the component by means such as generating a centrifugal force by rotations of centrifugal force generating mechanism. More specifically, for example, the component may be clamped by fixture to undergo spinning and drainage. In one embodiment, the negative pressure vacuum drying device 400 dries the component in the cleaning chamber by means of temperature, blowing, negative pressure and/or vacuum.

In one embodiment, the cleaning chamber 100, the nanobubble generator 200, the drainage device 300 and the negative pressure vacuum drying device 400 operate in sequence, such that processes from cleaning to drying performed on the component (for example, the first component C1 and/or the second component C2) in the cleaning chamber 100 are completed in a one-stop manner. Thus, in addition to enhancing cleaning effects for a semiconductor carrier and further improving the issues of harmful substances such as contaminants and volatile organic compounds (VOC) remaining in a semiconductor carrier, a comprehensive one-stop cleaning process within one cleaning system for a semiconductor carrier can be effectively implemented, further achieving effects of reducing the space needed for configuring cleaning equipment and a lengthy operation time of cleaning procedures in different stops.

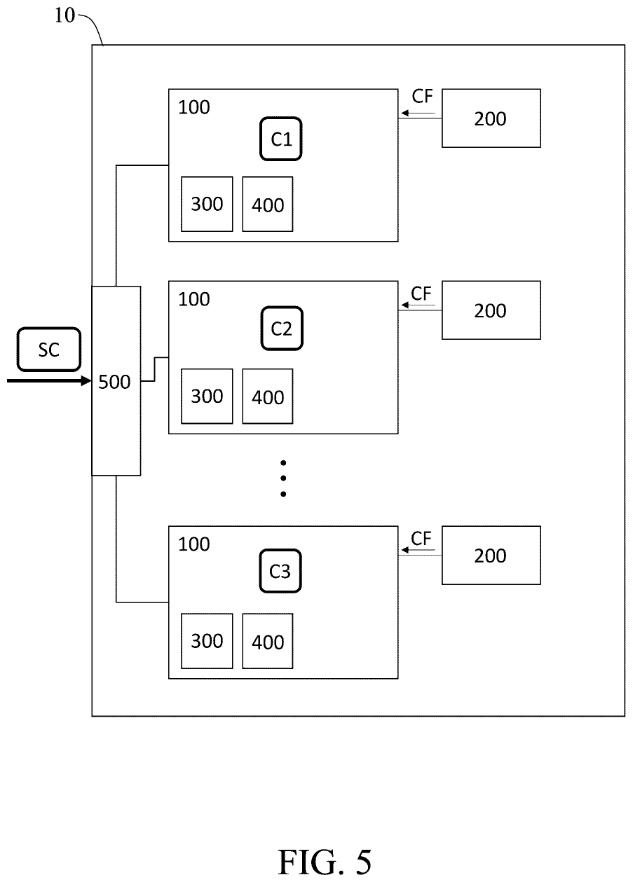

Referring to FIG. 5, in one embodiment, the semiconductor carrier cleaning system 10 includes a disassembly device 500 that disassembles and separates the components (for example, the first component C1, the second component C2 and the third component C3) of the different classes of the semiconductor carrier SC, and classifies and transports the components to the corresponding cleaning chambers 100. In one embodiment, the semiconductor carrier SC is, for example, a Front Opening Unified Pod (FOUP), and the multiple disassembled components are, for example, a pod body (for example, the first component C1) and a cover (for example, the second component C2) of the FOUP; however, the disassembled components are not limited to the examples above. In some embodiments, the semiconductor carrier SC may be further disassembled into different components. With the disassembly device 500, the semiconductor carrier SC may be disassembled into different components. These different components have different characteristics, for example, sizes, shapes, physical properties and chemical properties, and can correspond to different subsequent processing processes in different cleaning chambers 100. In one embodiment, the disassembly device 500 includes, for example, a mechanical arm to disassemble the semiconductor carrier SC.

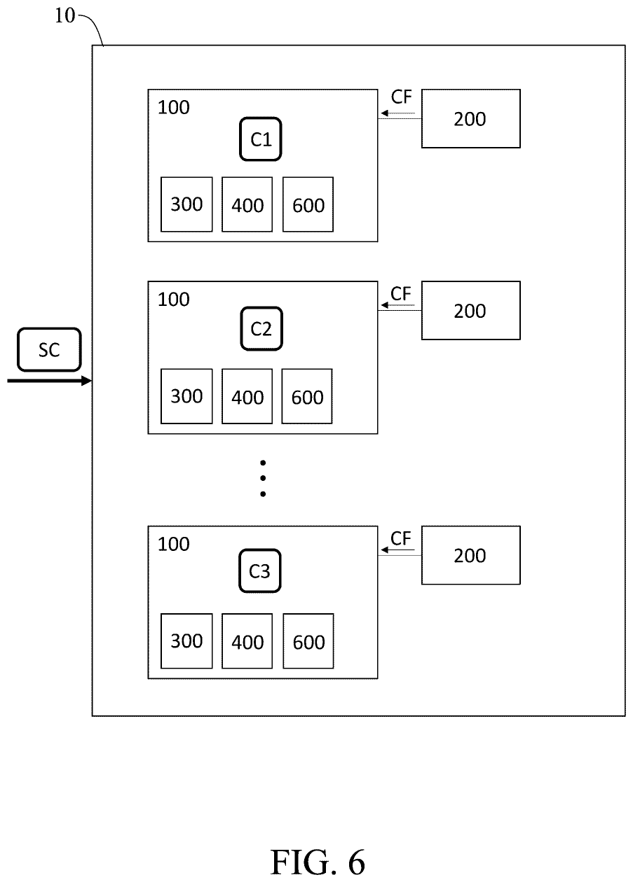

Referring to FIG. 6, in one embodiment, the semiconductor carrier cleaning system 100 includes at least one ultrasonic vibration device 600 arranged in the cleaning chamber 100. The ultrasonic vibration device 600 vibrates and stirs the cleaning fluid CF in the cleaning chamber 100 by generating high-frequency sound waves to clean the component (for example, the first component C1, the second component C2, and/or the third component C3) by means of performing ultrasonic vibration. Thus, by reinforcing cleaning of the component by means of ultrasonic vibration, the efficiency for removing contaminants and chemical substances from the component is improved. In one embodiment, the amplitude and frequency of ultrasonic waves generated by the ultrasonic vibration device 600 are adjustable, and are also adjustable according to the properties of different components.

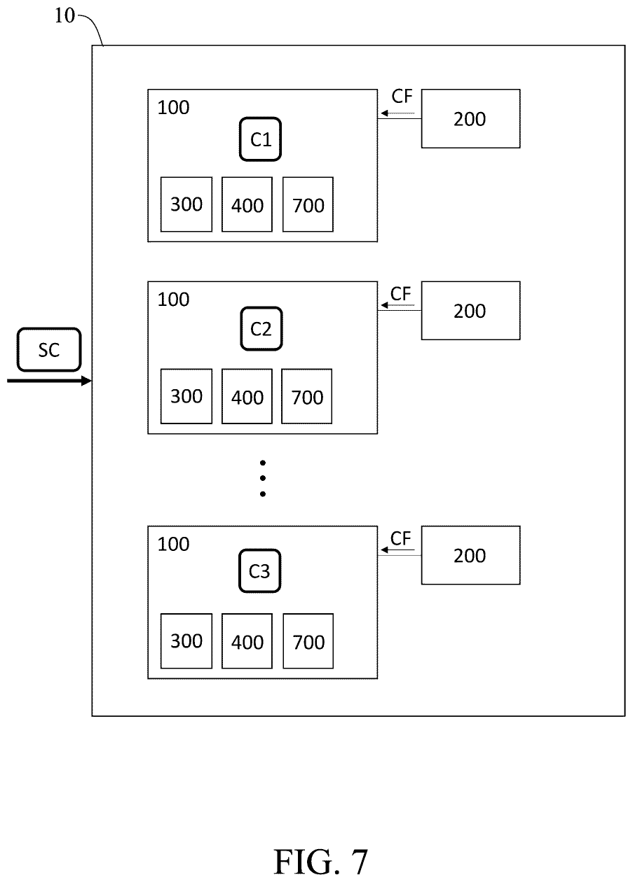

Referring to FIG. 7, in one embodiment, the semiconductor carrier cleaning system 10 includes at least one heating device 700 arranged in the cleaning chamber 100. The heating device 700 is for heating the cleaning fluid CF in the cleaning chamber 100. In one embodiment, the heating device 700 may be an electric heater, a heating panel, a hot steam generating device or an infrared heating device; however, the present disclosure is not limited to the examples above. In one embodiment, with the heating device 700 provided in the cleaning chamber 100, the efficiency for removing contaminants and chemical substances from the component is improved by means of heating the cleaning fluid CF in the cleaning chamber 100. In one embodiment, the heating temperature of the heating device 700 is adjustable, and is also adjustable according to the properties of different components.

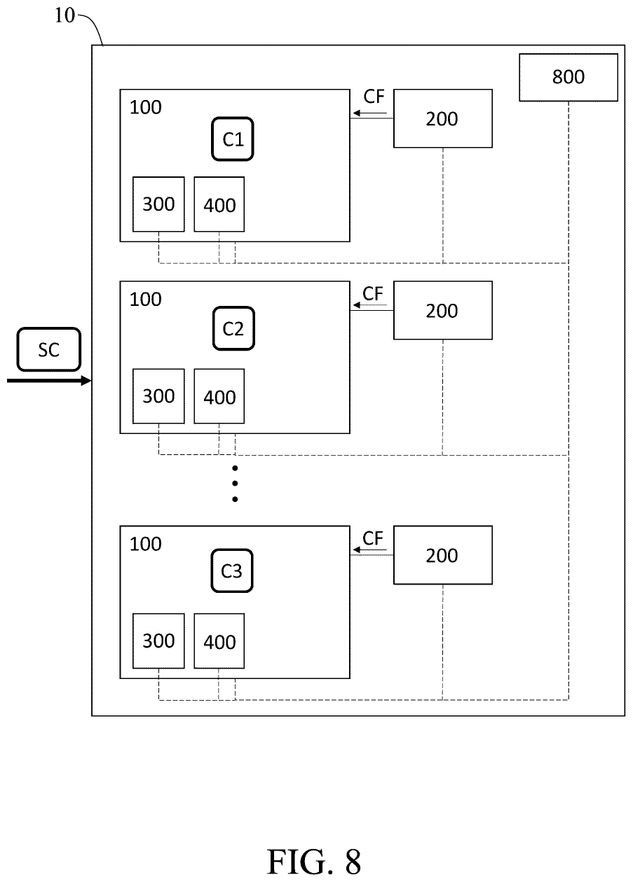

Referring to FIG. 8, in one embodiment, the semiconductor carrier cleaning system 10 includes a backend system 800, which is signally connected to the cleaning chamber 100, the nanobubble generator 200, the drainage device 300 and the negative pressure vacuum drying device 400. The backend system 800 is for controlling the cleaning chamber 100, the nanobubble generator 200, the drainage device 300 and the negative pressure vacuum drying device 400 operate in sequence, such that processes from cleaning to drying for the component (for example, the first component C1, the second component C2 and/or the third component C3) in the cleaning chamber 100 are completed in a one-stop manner. In one embodiment, the cleaning process of the nanobubble generator 200 controls and sets parameters by the backend system 800 to accordingly correspond to cleaning conditions of all of the components of different classes. In one embodiment, the backend system 800 is for controlling and integrating the operations and sequences of the cleaning chamber 100, the nanobubble generator 200, the drainage device 300 and the negative pressure vacuum drying device 400. In one embodiment, the backend system 800 may be, for example, the electronic device above in any form, so as to provide a device and/or a user interface for controlling and setting parameters, and may also be signally coupled to the devices or equipment corresponding to the individual steps above, or may correspond to different classes of components and be stored with at least one cleaning process.

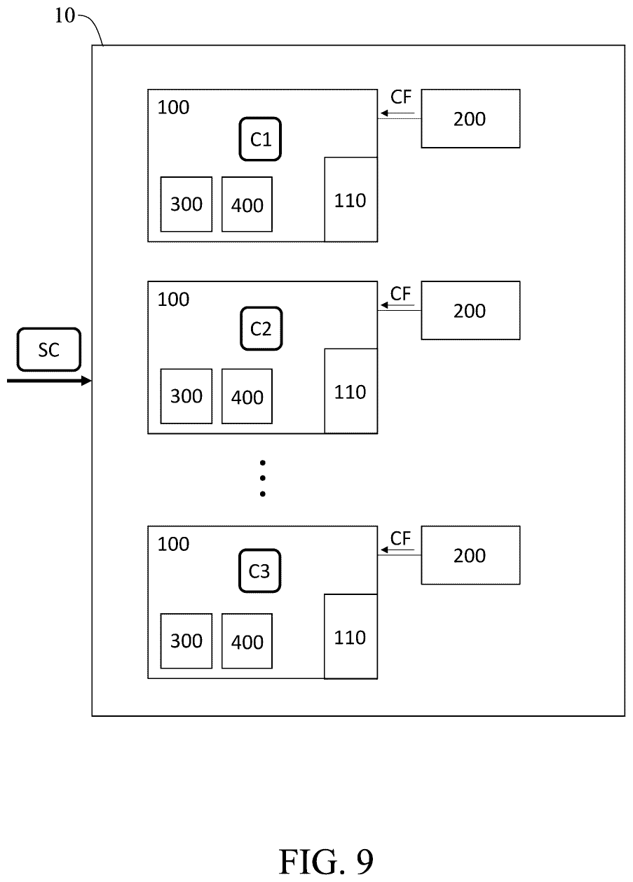

Referring to FIG. 9, each of the cleaning chambers 100 of the semiconductor carrier cleaning system 10 further includes an overflow port 110, and a circulation space in the cleaning chamber 100 is defined between the overflow port 110 and the nanobubble generator 200 to circulate and replace the cleaning fluid CF in the cleaning chamber 100. In one embodiment, the cleaning chamber 100 is provided with the overflow port 110 for discharging the cleaning fluid CF from the cleaning chamber and at the same time continually inputting the cleaning fluid CF to circulate and replace the cleaning fluid CF in the cleaning chamber 100, thereby discharging the cleaning fluid CF carrying the contaminants and/or chemical substances and replacing the same by a clean cleaning fluid CF and hence preventing secondary contamination of the components and improving cleaning effects.

In one embodiment, the devices above may be provided as desired in the semiconductor carrier cleaning system 10 according to different combinations, configurations and requirements, and are not limited to the specific examples above.

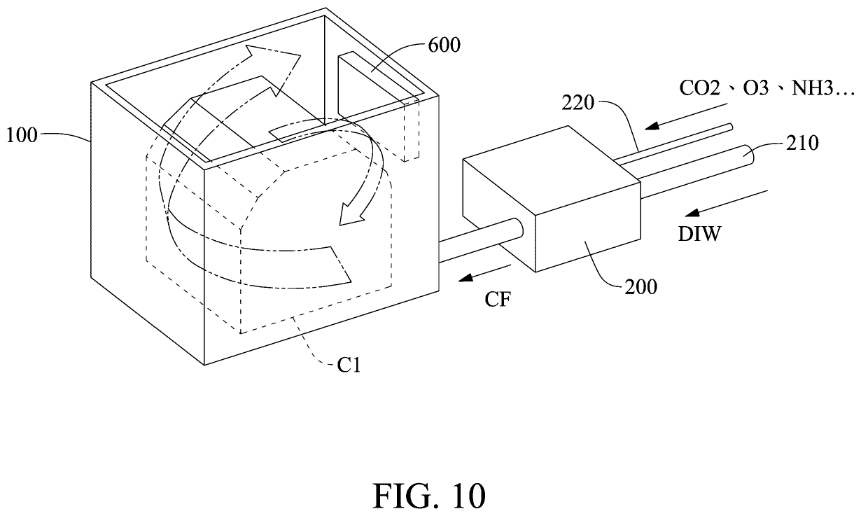

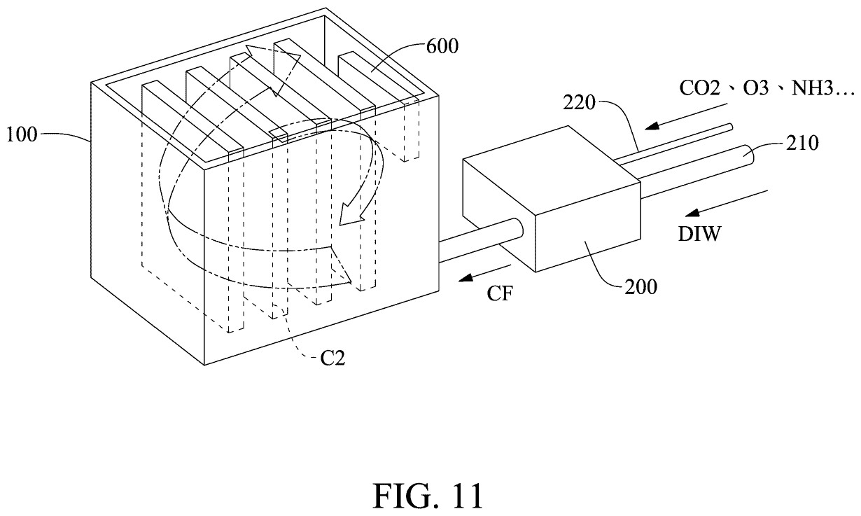

FIG. 10 shows a partial configuration diagram of a cleaning system for a semiconductor carrier according to an embodiment of the present disclosure. FIG. 11 shows a partial configuration diagram of a cleaning system for a semiconductor carrier according to an embodiment of the present disclosure.

Referring to FIG. 10 and FIG. 11, FIG. 10 shows a partial configuration diagram of a cleaning system for a semiconductor carrier according to an embodiment of the present disclosure, wherein the first component C1 (for example, a pod body of an FOUP) is placed in the cleaning chamber 100. FIG. 11 shows a partial configuration diagram of a cleaning system for a semiconductor carrier according to an embodiment of the present disclosure, wherein the second component C2 (for example, a cover of an FOUP) is placed in the cleaning chamber 100.

Referring to both FIG. 10 and FIG. 11, the cleaning chamber 100 is provided with the ultrasonic vibration device 600, and the nanobubble generator 200 is connected to the cleaning chamber 100 by a pipeline to transport the cleaning fluid CF. Moreover, the nanobubble generator 200 is connected to a fluid duct 210 to receive deionized water (DIW), and is connected to an air duct 220 to receive a gas for generating nanobubbles, for example, carbon dioxide (CO₂), ozone (O₃), ammonia (NH₃) or other substances able to generate nanobubbles, so as to mix the same to generate the cleaning fluid CF having nanobubbles by the nanobubble generator 200. Furthermore, liquid flow may be generated in the cleaning chamber 100 according to configuration positions of the nanobubble generator 200 and its pipeline that inputs the cleaning fluid CF, so as to effectively clean the component in the cleaning chamber 100, for example, as shown by the arrows in the cleaning chamber 100 in FIG. 10 and FIG. 11. In one embodiment, the overflow port (not shown) above may be provided on an opposite side of the cleaning chamber 100 where a pipeline of the nanobubble generator 200 is arranged, so as to allow the cleaning fluid CF to fully flow in the cleaning chamber 100 and keep the cleaning fluid CF continually overflowing and thus circulating, thereby removing contaminants floating in the cleaning fluid CF and on the surface. In one embodiment, the overflow port (not shown) above may be provided on an upper side of the cleaning chamber 100 where a pipeline of the nanobubble generator 200 is arranged, so as to allow the cleaning fluid CF to fully flow in the cleaning chamber 100 and allow the cleaning fluid CF overflow more easily and circulate effectively, thereby removing contaminants floating in the cleaning fluid CF and on the surface.

Thus, with integrated steps of disassembly, classification, nanobubble washing and negative pressure vacuum drying provided by the one-stop cleaning method for a semiconductor carrier and cleaning system for a semiconductor carrier of the present disclosure, cleaning effects for a semiconductor carrier can be enhanced effectively to improve the issues of harmful substances such as contaminants and volatile organic compounds, toluene and isopropanol remaining in a semiconductor carrier, and a comprehensive one-stop cleaning process within one cleaning system can be effectively achieved. In addition, differentiated cleaning can be performed with respect to each semiconductor carrier and its components, further achieving the effect of reducing the space needed for configuring cleaning equipment and a lengthy operation time of cleaning procedures in different stops. Moreover, with the ultrasonic vibration device, the heating device, the backend system, the soaking step and the overflow step, cleaning effects of the cleaning method and system for a semiconductor carrier are further improved to increase the level of cleanliness of a semiconductor carrier.

The present invention is described by way of the embodiments above. A person skilled in the art should understand that, these embodiments are merely for describing the present invention and are not to be construed as limitations to the scope of the present invention. It should be noted that all equivalent changes, replacements and substitutions made to the embodiments are to be encompassed within the scope of the present invention. Therefore, the protection of the present disclosure should be accorded with the broadest interpretation of the appended claims, so as to encompass all modifications and similar arrangements and processes.

While the present disclosure has been described by means of specific embodiments, numerous modifications and variations could be made thereto by those skilled in the art without departing from the scope and spirit of the present disclosure set forth in the claims.

What is claimed is:

1. A cleaning method for a semiconductor carrier, comprising steps of:
a disassembly step of disassembling a semiconductor carrier to be cleaned into a plurality of components;
a classification step of classifying the plurality of components and respectively placing the plurality of components into cleaning chambers of corresponding classes;
a nanobubble washing step of cleaning the components in the individual cleaning chambers by the cleaning chambers with the cleaning processes set according to characteristics of the components to be cleaned; and
a negative pressure vacuum drying step of drying the components inside the individual cleaning chambers by the individual cleaning chambers.

2. The cleaning method for a semiconductor carrier according to claim 1, wherein in the nanobubble washing step, a cleaning fluid is transported to the cleaning chamber by the nanobubble generator to fully clean micropores of the component.

3. The cleaning method for a semiconductor carrier according to claim 2, wherein the cleaning fluid is deionized water mixed with carbon dioxide, ozone or ammonia.

4. The cleaning method for a semiconductor carrier according to claim 1, wherein in the nanobubble washing step, the cleaning chamber is provided with an ultrasonic vibration device, and the cleaning fluid in the cleaning chamber is stirred by generating high-frequency sound wave vibration to clean the component by means of performing ultrasonic vibration.

5. The cleaning method for a semiconductor carrier according to claim 1, wherein in the nanobubble washing step, the cleaning chamber is provided with a heating device for heating the cleaning fluid in the cleaning chamber.

6. The cleaning method for a semiconductor carrier according to claim 5, after the cleaning fluid is heated, further comprising a soaking step of soaking the component until a predetermined decontamination condition is met, wherein the predetermined decontamination condition is that 50% or more of decontamination of the component is met.

7. The cleaning method for a semiconductor carrier according to claim 1, wherein in the nanobubble washing step, the cleaning process controls and sets parameters by a backend system to accordingly correspond to cleaning conditions of all of the components of different classes.

8. The cleaning method for a semiconductor carrier according to claim 1, wherein the nanobubble washing step further comprises an overflow step for circulating and replacing the cleaning fluid in the cleaning chamber.

9. The cleaning method for a semiconductor carrier according to claim 1, before the negative pressure vacuum drying step, further comprising a drainage step of fully discharging the cleaning fluid from the cleaning chamber and eliminating partial fluid attached to the component.

10. A cleaning system for a semiconductor carrier, adapted to clean the semiconductor carrier comprising a plurality of components of different classes, the cleaning system for a semiconductor carrier comprising:
a plurality of cleaning chambers, each of the cleaning chambers arranged with the component of different classes; and
at least one nanobubble generator, coupled to the cleaning chamber, the nanobubble generator for transporting a cleaning fluid to at least one of the cleaning chambers to fully clean micropores of the component;
wherein, the cleaning chamber comprises:
at least one drainage device, arranged at the cleaning chamber, the drainage device fully discharging the cleaning fluid from the cleaning chamber and eliminating partial fluid attached to the component; and
at least one negative pressure vacuum drying device, arranged at the cleaning chamber, the negative pressure vacuum drying device for drying the component in the cleaning chamber; and
wherein, the cleaning chamber, the nanobubble generator, the drainage device and the negative pressure vacuum drying device operate in sequence, such that processes from cleaning to drying for the component are completed in a one-stop manner.

11. The cleaning system for a semiconductor carrier according to claim 10, further comprising a disassembly device to disassemble and separate the components of the different classes of the semiconductor carrier, and transport the same into the corresponding cleaning chamber.

12. The cleaning system for a semiconductor carrier according to claim 10, further comprising at least one ultrasonic vibration device arranged in the cleaning chamber, the ultrasonic vibration device stirring the cleaning fluid in the cleaning chamber by generating high-frequency sound wave vibration to clean the component by means of performing ultrasonic vibration.

13. The cleaning system for a semiconductor carrier according to claim 10, further comprising a heating device arranged in the cleaning chamber, the heating device for heating the cleaning fluid in the cleaning chamber.

14. The cleaning system for a semiconductor carrier according to claim 10, further comprising a backend system for controlling the cleaning chamber, the nanobubble generator, the drainage device and the negative pressure vacuum drying device to operate in sequence, such that processes from cleaning to drying for the component are completed in a one-stop manner.

15. The cleaning system for a semiconductor carrier according to claim 10, wherein each of the cleaning chambers further comprises an overflow port, and a circulation space in the cleaning chamber is defined between the overflow port and the nanobubble generator to circulate and replace the cleaning fluid in the cleaning chamber.

16. The cleaning system for a semiconductor carrier according to claim 10, wherein the cleaning fluid is deionized water mixed with carbon dioxide, ozone or ammonia.
